(19) United States
(12) Patent Application Publication
(10) Pub. No.: US 2012/0129341 A1
(43) Pub. Date: May 24, 2012

(54) METHOD FOR FABRICATING VIA HOLE AND THROUGH-SILICON VIA

(75) Inventors: Seung Hee JO, Seongnam-si (KR); Seong Cheol KIM, Anseong-si (KR)

(73) Assignee: HYNIX SEMICONDUCTOR INC., Icheon-si (KR)

(21) Appl. No.: 13/187,845

(22) Filed: Jul. 21, 2011

(30) Foreign Application Priority Data
Nov. 19, 2010 (KR) 10-2010-0115715

(51) Int. Cl. H01L 21/28; H01L 21/311

(52) U.S. Cl. 438/653; 438/703; 257/E21.249; 257/E21.158

(57) ABSTRACT

A method for fabricating a via hole includes forming a first mask pattern on a first surface of a wafer exposing a portion of the first surface of the wafer, forming a passivation region within the wafer by implanting impurities into the exposed portion of the wafer using the first mask pattern as an ion implantation barrier layer, forming an etching stop layer on the first surface of the wafer including the passivation regions, forming a second mask pattern on a second surface of the wafer faces away from the first surface of the wafer, wherein the second mask pattern exposes a portion of the second surface of the wafer over an area between the passivation regions, and forming a via hole by etching the wafer using the second mask pattern as an etching mask.

### CROSS-REFERENCES TO RELATED APPLICATIONS

The present application claims priority under 35 U.S.C 119(a) to Korean Application No. 10-2010-0115715, filed on Nov. 19, 2010, in the Korean intellectual property Office, which is incorporated herein by reference in its entirety set forth in full.

### BACKGROUND

Exemplary embodiments of the present invention relate to a fabrication of a semiconductor device, and more particularly, to a method for fabricating a via hole and a through-silicon via (TSV).

Recently, as electronic products become smaller in size and provide higher performance, the demands for ultra-small high-capacity semiconductor memory devices are increasing. Semiconductor memory manufacturers are making many efforts to increase a storage capacity of a semiconductor memory device through a multi chip package in which a plurality of semiconductor chips are mounted in a single semiconductor package.

A multi chip package technology can reduce a manufacturing cost of a package through a simplified process and is advantageous to mass production, but it has a disadvantage in that an interconnection space for electrical connection within a package is insufficient due to the increase in the number and size of chips to be stacked. In this regard, a package structure using TSVs has been proposed. The package using TSVs is designed so that TSVs are formed within chips at a wafer level, and the chips are physically and electrically coupled together by the TSVs.

However, notch phenomenon may occur when via holes are formed in order to implement the TSVs. That is, the lower side walls of the via holes are excessively etched.

FIG. 1 is a cross-sectional view explaining notch phenomenon occurring during a process of forming a via hole.

Referring to FIG. 1, an etching source 30 is supplied to a wafer 10, and a via hole 25 is formed within the wafer 10. The etching process for forming the via hole 25 is performed until the surface of an etching stop layer 20 is exposed. However, due to a thickness difference between a center portion and an edge portion of the wafer 10, an amount etched at the center portion of the wafer 10 may be different from an amount etched at the edge portion of the wafer 10. For example, the etching is completed at the relatively thin center portion of the wafer 10 earlier than at the edge portion of the wafer 10, and thus the surface of the etching stop layer 20 at the center portion of the wafer is exposed. However, the center portion of the wafer 10 is exposed to the etching source 30 until the etching of the edge portion of the wafer 10 is completed. Therefore, although the top surface of the wafer 10 covered by a mask 15 may not be influenced by the etching source 30, the etching source 30 may be accumulated on the lower portion of the via hole 25, that is, the interface between the wafer 10 and the etching stop layer 20. Consequently, due to the accumulated etching source 30, the wafer 10 under the lower portion of the via hole 25 may be excessively etched, and thus a notch 35 may be formed. When the notch 35 is formed at the lower portion of the via hole 25, filling the via hole 25 in a subsequent process may be difficult, a device failure may occur.

### SUMMARY

An embodiment of the present invention is directed to a method for fabricating a via hole and a TSV, which can prevent the occurrence of notch phenomenon at a lower side wall of a via hole during a process of forming a TSV.

In an exemplary embodiment, a method for fabricating a via hole includes forming a first mask pattern on a first surface of a wafer exposing a portion of the first surface of the wafer, forming a passivation region within the wafer by implanting impurities into the exposed portion of the wafer using the first mask pattern as an ion implantation barrier layer, forming an etching stop layer on the first surface of the wafer including the passivation regions, forming a second mask pattern on a second surface of the wafer faces away from the first surface of the wafer, wherein the second mask pattern exposes a portion of the second surface of the wafer over an area between the passivation regions, and forming a via hole by etching the wafer using the second mask pattern as an etching mask.

In another exemplary embodiment, a method for forming a through-silicon via includes forming a first mask pattern on a first surface of a wafer exposing a portion of the first surface of the wafer, forming a passivation region within the wafer by implanting impurities into the exposed portion of the wafer using the first mask pattern as an ion implantation barrier layer, forming an etching stop layer on the first surface of the wafer including the passivation regions, forming a second mask pattern on a second surface of the wafer faces away from the first surface of the wafer, wherein the second mask pattern exposes a portion of the second surface of the wafer over an area between the passivation regions, forming a via hole by etching the wafer using the second mask pattern as an etching mask, forming a barrier metal layer on the exposed surface of the via hole, and forming a through-silicon via passing through the wafer by filling the via hole.

### BRIEF DESCRIPTION OF THE DRAWINGS

The above and other aspects, features and other advantages will be more clearly understood from the following detailed description taken in conjunction with the accompanying drawings, in which:

FIG. 1 is a cross-sectional view explaining notch phenomenon occurring during a process of forming a via hole; and

FIGS. 2 to 10 are cross-sectional views illustrating a method for fabricating a via hole and a TSV according to an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

FIGS. 2 to 10 are cross-sectional views illustrating a method for fabricating a via hole and a TSV according to an embodiment of the present invention.

Referring to FIG. 2, a first mask pattern 205 is formed on a silicon wafer 200, in which a plurality of semiconductor chips are formed, so that a portion of the surface of the silicon wafer 200 is exposed. The first mask pattern 205 may be formed of a resist layer. In this case, the first mask pattern 205 is formed on a first surface of the silicon wafer 200, for example, a front side thereof.

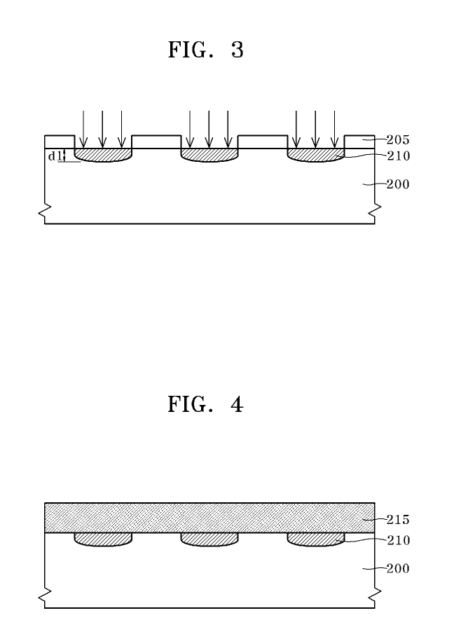

Referring to FIG. 3, a passivation region 210 is formed within the silicon wafer 200 by performing an ion implantation process on the silicon wafer 200. Specifically, the ion implantation process is performed to implant impurities into the exposed surface of the silicon wafer 200 using the first mask pattern 205 as an ion implantation barrier layer, as indicated by arrows. Here, impurities, which can change silicon of the silicon wafer 200 into a material having an etching selectivity to the silicon, are implanted. In the exemplary embodiment of the present invention, impurities containing oxygen (O₂) ions may be implanted. If the impurities containing oxygen (O₂) ions are implanted into the silicon wafer 200, the passivation region 210 is formed by the reaction between the oxygen (O₂) ion and the silicon (Si) of the silicon wafer 200. In this case, the passivation region 210 is formed using a silicon-oxide (Si-Ox) material layer. The ion implantation process is performed while adjusting an ion implantation concentration and an ion implantation intensity of the impurities containing the oxygen (O₂) ions, so that a depth d1 of the passivation region 210 does not exceed a certain depth, e.g., 5 μm from the exposed surface of the silicon wafer 200.

The ion implantation process may be performed in a horizontal direction as well as a vertical direction. In a case in which the passivation region 210 is formed to have a depth greater than 5 μm, the impurities may be diffused in a horizontal direction. Thus, the passivation region 210 may extend to a region blocked by the first mask pattern 205, e.g., a region at which a via hole is to be formed. In this case, the via hole may not be formed in an impurity diffusion region in a subsequent process, thus a device failure may occur. Therefore, the passivation region 210 is formed to have a depth of 5 μm or less from the exposed surface of the silicon wafer 200.

The passivation region 210 serves to protect the silicon wafer 200 from the etching source 30 in a subsequent etching process for forming a TSV, which will be described later in detail. After the ion implantation process, the first mask pattern 205 is removed by a strip process.

Referring to FIG. 4, an etching stop layer 215 is formed on the passivation region 210 and the silicon wafer 200, the surface of which is exposed by the removal of the first mask pattern (205 in FIG. 3). The etching stop layer 215 serves to designate a position at which the etching is to be stopped in a subsequent etching process for forming a TSV. The etching stop layer 215 may be formed of a material having an etching selectivity to the silicon wafer 200. Silicon oxide (SiO₂) may be used as the material having an etching selectivity to the silicon wafer 200.

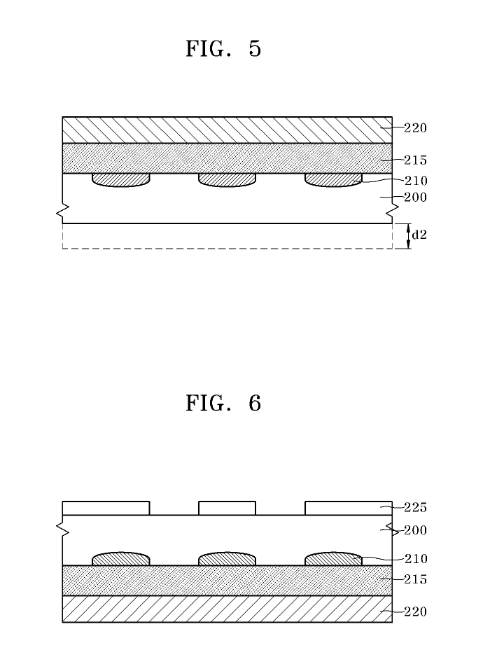

Referring to FIG. 5, a carrier wafer 220 is attached to the etching stop layer 215. A second surface of the silicon wafer 200, which faces away from the first surface to which the etching stop layer 215 and the carrier wafer 220 are attached, that is, a back side of the silicon wafer 200 is recessed by a first depth d2.

Referring to FIG. 6, a second mask pattern 225 exposing a portion of the surface of the silicon wafer 200, at which a TSV is to be formed, is formed on the silicon wafer 200 recessed by the first depth d2. The second mask pattern 225 may be formed using a resist layer. In order to apply a method of forming a via hole from the back side of the silicon wafer 200 among methods of forming a TSV, the second mask pattern 225 is formed on the second surface (e.g., the back side) facing away from the first surface of the silicon wafer 200. In this case, the surface of the back side of the silicon wafer 200 exposed by the second mask pattern 225 exposes the surface of the regions other than the region where the passivation layer 210 is to be formed.

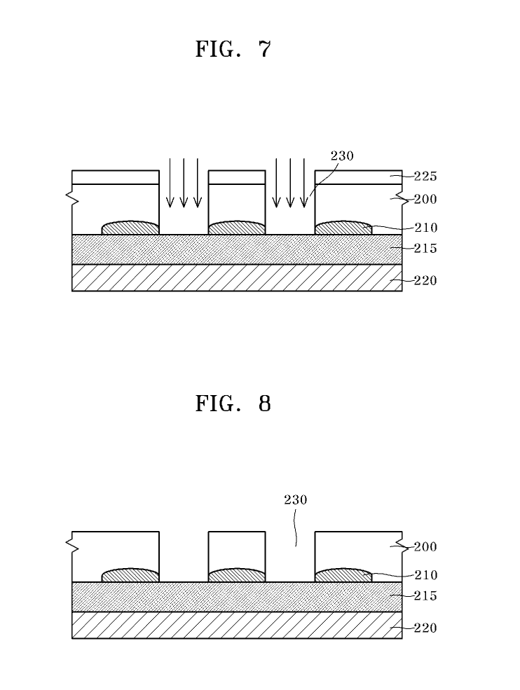

Referring to FIG. 7, an etching process using the second mask pattern 225 as an etching mask is performed to etch the exposed surface of the back side of the silicon wafer 200 to thereby form a via hole 230. Specifically, using the second mask pattern 225 as an etching mask, an etching source is supplied to the silicon wafer 200. The etching process may be performed by supplying a dry etching source or a wet etching source which can etch silicon. For example, the etching source which can etch silicon includes fluorine (F), and thus the etching process may be performed by supplying an etching source containing CF₄ gas. When the etching source is supplied to the silicon wafer 200, the silicon wafer 200 is etched to form a via hole 230, as indicated by arrows. The etching process for forming the via hole 230 may be performed until the etching of the silicon of the silicon wafer 200 is completed and the surface of the etching stop layer 215 is exposed.

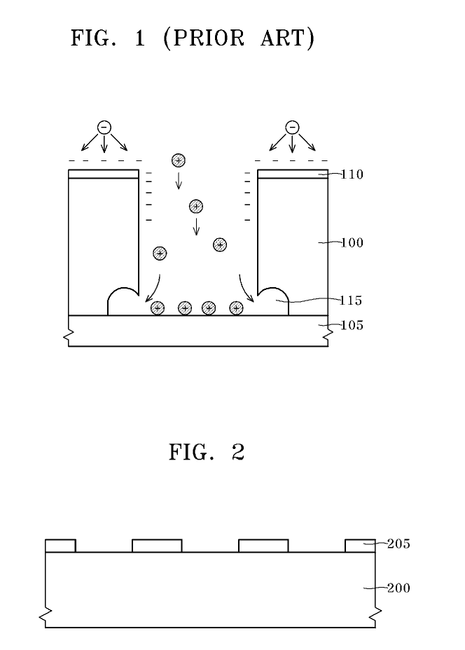

During the etching process for forming the via hole 230 within the silicon wafer 200, the passivation region 210 is exposed at a lower side wall of the via hole 230. The passivation region 210 is formed of a material having an etching selectivity to silicon (Si), for example, silicon oxide (SiO₂). Accordingly, the lower side wall of the via hole 230, at which the passivation region 210 is formed, is not etched by the silicon etching source. That is, since the passivation region 210 serves as an etching barrier layer, the silicon wafer 200 may not be influenced by the etching process. Therefore, the occurrence of notch (35 in FIG. 1), caused when the etching source is accumulated at the interface between the etching stop layer and the silicon wafer during the etching process for forming the via hole and thus the silicon wafer is etched by the accumulated etching source, may decrease.

Referring to FIG. 8, the second mask pattern (225 in FIG. 7) serving as the etching mask for forming the via hole 230 is removed. Thus, the surface of the etching layer 215 is exposed by the via hole 230 formed in a region where a TSV is to be formed.

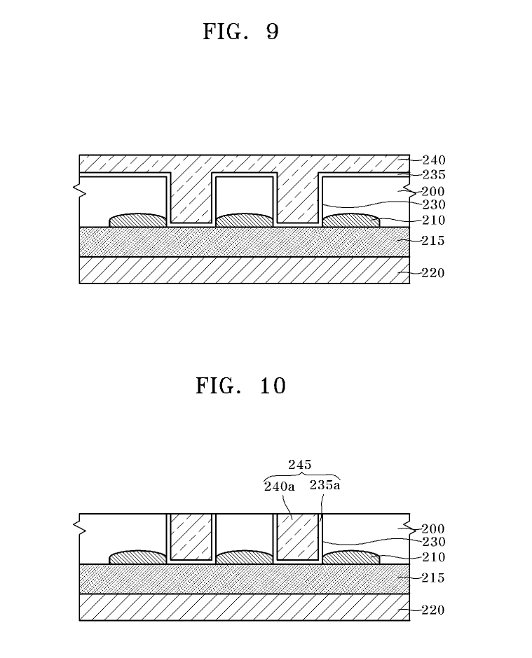

Referring to FIG. 9, a barrier metal layer 235 is formed over the silicon wafer 200 where the via hole 230 is formed. Then, a seed metal layer is formed on the barrier metal layer 235. An electrolyte plating process is performed within the via hole 230 to fill the via hole 230 with an electrolyte material, i.e., a metal layer 240. The barrier metal layer 235 includes at least one selected from the group consisting of titanium nitride (TiN), titanium (Ti), and titanium tungsten (TiW). The barrier metal layer 235 serves to prevent the reaction between the metal layer 240 and the silicon wafer 200 or the passivation region 210. In addition, the metal layer 240 filling the via hole 230 includes a monolayer or multilayer selected from the group consisting of gold (Au), copper (Cu), tungsten (W), and poly-Si compound.

Referring to FIG. 10, considering a total thickness in a stack package fabrication, the metal layer (240 in FIG. 9) and the barrier metal layer (235 in FIG. 9) are etch-backed to expose the surface of the silicon wafer 200. Accordingly, a TSV 245 including a barrier metal pattern 235a and the metal pattern 240a filling the via hole 230 is formed.

According to the exemplary embodiments of the present invention, when the method of forming the via hole from the back side of the silicon wafer is applied to the implementation of the TSV, the ion implantation process of implanting impurities into the surface of the silicon wafer is performed to form the passivation region which is not etched by the silicon etching source. In this manner, notch phenomenon may be controlled. Consequently, the reliability of the package fabrication process and the process margin may be improved.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for fabricating a via hole, comprising:
forming a first mask pattern on a first surface of a wafer exposing a portion of the first surface of the wafer;
forming a passivation region within the wafer by implanting impurities into the exposed portion of the first surface of the wafer using the first mask pattern as an ion implantation barrier layer;
forming an etching stop layer on the first surface of the wafer including the passivation regions;
forming a second mask pattern on a second surface of the wafer faces away from the first surface of the wafer, wherein the second mask pattern exposes a portion of the second surface of the wafer over an area between the passivation regions; and
forming a via hole by etching the wafer using the second mask pattern as an etching mask.

2. The method of claim 1, further comprising, after forming the etching stop layer:
attaching a carrier wafer on the etching stop layer; and
recessing the second surface of the wafer by a first depth.

3. The method of claim 1, wherein the first surface of the wafer is a front side of the wafer, and the second surface of the wafer is a back side of the wafer.

4. The method of claim 1, wherein the forming of the passivation region comprises:
implanting impurities containing oxygen (O₂) ions into the exposed portion of the first surface of the wafer; and
forming the passivation region by inducing reaction between silicon of the wafer and the oxygen (O₂) ions.

5. The method of claim 4, wherein the passivation region is formed into a silicon-oxide (Si-Ox) material layer by the inducing reaction.

6. The method of claim 1, wherein the passivation region is formed to have a depth of 5 μm or less from the surface of the wafer.

7. The method of claim 1, wherein the etching stop layer comprises a material having an etching selectivity to a constituent material of the wafer.

8. The method of claim 6, wherein the etching stop layer comprises a silicon oxide layer.

9. The method of claim 1, wherein the via hole is formed by supplying a dry etching source or a wet etching source to the wafer.

10. The method of claim 1, wherein a lower side wall of the via hole is protected by the passivation region, whereby the via hole is formed in a vertical shape.

11. A method for forming a through-silicon via, comprising:
forming a first mask pattern on a first surface of a wafer exposing a portion of the first surface of the wafer;
forming a passivation region within the wafer by implanting impurities into the exposed portion of the first surface of the wafer using the first mask pattern as an ion implantation barrier layer;
forming an etching stop layer on the first surface of the wafer including the passivation regions;
forming a second mask pattern on a second surface of the wafer faces away from the first surface of the wafer, wherein the second mask pattern exposes a portion of the second surface of the wafer over an area between the passivation regions;
forming a via hole by etching the wafer using the second mask pattern as an etching mask;
forming a barrier metal layer on the exposed surface of the via hole; and
forming a through-silicon via passing through the wafer by filling the via hole.

12. The method of claim 11, wherein the first surface of the wafer is a front side of the wafer, and the second surface of the wafer is a back side of the wafer.

13. The method of claim 11, wherein the forming of the passivation regions comprises:
implanting impurities containing oxygen (O₂) ions into the exposed portion of the first surface of the wafer; and
forming the passivation region by inducing reaction between silicon of the wafer and the oxygen (O₂) ions.

14. The method of claim 13, wherein the passivation region is formed into a silicon-oxide (Si-Ox) material layer by the inducing reaction.

15. The method of claim 11, wherein the passivation region is formed to have a depth of 5 μm or less from the surface of the wafer.

16. The method of claim 11, wherein a lower side wall of the via hole is protected by the passivation region, whereby the via hole is formed in a vertical shape.
